(19) United States
(12) Patent Application Publication
(10) Pub. No.: US 2009/0187344 A1
(43) Pub. Date: Jul. 23, 2009

(54) System, Method, and Computer Program Product for Analyzing Power Grid Data

(76) Inventors: Daniel S. Brancaccio, Coronado, CA (US); David G. Kreiss, San Diego, CA (US)

Correspondence Address: CAPITAL LEGAL GROUP, LLC, 1100 River Bay Road, Annapolis, MD, 21409, US

(21) Appl. No.: 12/355,361

(22) Filed: Jan. 16, 2009

Related U.S. Application Data
(60) Provisional application No. 61/022,320, filed on Jan. 19, 2008.

(51) Int. Cl. G06F 19/00; G01R 21/00; G01R 31/02

(52) U.S. Cl. 702/4; 702/60; 702/58

(57) ABSTRACT

A system, device and method for analyzing power grid data is provided. In one embodiment, the system includes a data collection module comprising a plurality of database adapters configured to retrieve non-operational utility data, a data storage module in communication with said data collection module and comprising a database for storing the non-operational utility data, and an analysis and reporting module in communication with said data storage module and configured to process the non-operational data and to provide a plurality of reports and a plurality of alarms. The analysis and reporting module may comprise an object library comprising a plurality of objects and wherein each object is configured to perform a specific analysis of utility data, an analysis rules module linking one or more objects of the object library and defining an analysis to be performed, an analysis engine configured to execute the analysis rules module, and a report generator configured to produce a report based on an output of the analysis rule module.

### CROSS REFERENCE TO RELATED APPLICATIONS

This application claims the benefit of U.S. Provisional Application No. 61/022,320, filed Jan. 19, 2008, entitled “System and Method for Analyzing Power Line Data,” which is incorporated herein by reference in its entirety for all purposes.

### FIELD OF THE INVENTION

The present invention generally relates to systems and methods for managing power transmission and distribution systems, and more particularly to systems and methods for analyzing power grid data.

### BACKGROUND OF THE INVENTION

The power grid infrastructure includes power lines, transformers and other devices for power generation, power transmission, and power delivery. A power source generates power, which is transmitted along high voltage (HV) power lines for long distances. Typical voltages found on HV transmission lines range from 69 kilovolts (kV) to in excess of 800 kV. The power signals are stepped down to medium voltage (MV) power signals at regional substation transformers. MV power lines carry power signals through neighborhoods and populated areas. Typical voltages found on MV power lines power range from about 1000 V to about 100 (69) kV. The voltages are stepped down further to low voltage (LV) at distribution transformers. LV power lines typically carry power having voltages ranging from about 100 V to about 600 V to customer premises.

In a typical a power grid, operating data is acquired from regional substations, and includes data such voltage and current supplied by the substations. For example, a supervisory control and data acquisition (SCADA) system, or other industrial distributed control system, may be implemented with access points at each regional substation.

The power line voltage and current collected by the SCADA system constitutes operational data. To better manage and control the power transmission and distribution systems it is desirable to obtain non-operational data, such as environmental data (e.g., lightening strikes, temperature, etc.), harmonics fault records, and equipment health data. Little, if any of such non-operational data has been available or processed to provide an actionable or valuable data.

A power line communication system may be implemented to provide communications over the power lines. Accordingly, data now may be acquired from various points within the power grid such as at distribution transformers and at power meters. It is desirable that both operational and non-operational data be acquired and processed. Further, there now is a need for a system and method of analyzing power grid data, and in particular, non-operational power grid data to more effectively manage a power grid (sometime referred to herein as power distribution network). These and other needs may be addressed by one or more embodiments of the present invention.

### SUMMARY OF THE INVENTION

The present invention provides a system and method for analyzing power grid data. In one embodiment, the system includes a data collection module comprising a plurality of database adaptors configured to retrieve non-operational utility data, a data storage module in communication with said data collection module and comprising a database for storing the non-operational utility data, and an analysis and reporting module in communication with said data storage module and configured to process the non-operational data and to provide a plurality of reports and a plurality of alarms. The analysis and reporting module may comprise an object library comprising a plurality of objects and wherein each object is configured to perform a specific analysis of utility data, an analysis rules module linking one or more objects of the object library and defining an analysis to be performed, an analysis engine configured to execute the analysis rules module, and a report generator configured to produce a report based on an output of the analysis rule module.

The invention will be better understood by reference to the following detailed description taken in conjunction with the accompanying drawings.

### BRIEF DESCRIPTION OF THE DRAWINGS

The invention is further described in the detailed description that follows, by reference to the noted drawings by way of non-limiting illustrative embodiments of the invention, in which like reference numerals represent similar parts throughout the drawings. As should be understood, however, the invention is not limited to the precise arrangements and instrumentalities shown. In the drawings:

FIG. 1 is a diagram of a data acquisition system environment, according to an example embodiment of the present invention;

FIG. 2 is a block diagram of the interrelationship between a non-operational data acquisition (NODA) system and an operational data acquisition system (e.g., SCADA), according to an example embodiment of the present invention;

FIG. 3 is a diagram of the integration between the NODA system and SCADA system, according to an example embodiment of the present invention;

FIG. 4 is a diagram of the integration between the NODA system and SCADA system, according to another example embodiment of the present invention;

FIG. 5 is a block diagram of NODA system modules, according to an example embodiment of the present invention;

FIG. 6 is a block diagram of NODA system components, according to an example embodiment of the present invention;

FIG. 7 is a data flow diagram of the data collection module, according to an example embodiment of the present invention;

FIG. 8 is a data flow diagram of data stored in a temporary file format, according to an example embodiment of the present invention;

FIG. 9 is a block diagram of various data collection configurations of the NODA system, according to an example embodiment of the present invention;

FIG. 10 is a block diagram of the analysis and reporting module's data analysis points, according to an example embodiment of the present invention;

FIG. 11 is a block diagram of the analysis engine module of the analysis and reporting module, according to an example embodiment of the present invention;

FIG. 12 is an illustration of an example fault report generated by an application of the NODA system, according to an example embodiment of the present invention;

FIG. 13 is an illustration of a portion of an example power quality report generated by an application of the NODA system, according to an example embodiment of the present invention;

FIG. 14 is an illustration of an example billing report generated by an application of the NODA system, according to an example embodiment of the present invention;

FIG. 15 is an illustration of an example chart generated by an application of the NODA system, according to an example embodiment of the present invention;

FIG. 16 is an illustration of an example interactive waveform report generated by an application of the NODA system, according to an example embodiment of the present invention; and

FIG. 17 is a flow chart of a utility data analysis method, according to an example embodiment of the present invention.

### DETAILED DESCRIPTION OF ILLUSTRATIVE EMBODIMENTS

In the following description, for purposes of explanation and not limitation, specific details are set forth, such as particular networks, devices, communication systems, computers, terminals, components, techniques, data and network protocols, power line communication systems (PLCSs), power grids, software products and systems, enterprise applications, operating systems, development interfaces, hardware, etc. in order to provide a thorough understanding of the present invention.

However, it will be apparent to one skilled in the art that the present invention may be practiced in other embodiments that depart from these specific details. Detailed descriptions of well-known networks, devices, communication systems, computers, terminals, components, techniques, data and network protocols, software products and systems, operating systems, development interfaces, and hardware are omitted so as not to obscure the description of the present invention.

The present invention comprises a system and method of collecting and processing non-operational data. According to an example embodiment of the present invention, a non-operational data acquisition (NODA) system may be implemented to complement an operational data acquisition system, such as a conventional supervisory control and data acquisition (SCADA) system. Operational data for a utility's power transmission and distribution network generally includes the real time circuit voltages, currents, watts, and VARs collected by the SCADA system or the like at each substation, along with the status of circuit breakers at the various substations. Typically such data is collected every 3-5 seconds by the SCADA system. While operational data typically indicates what is happening, non-operational data is collected for use typically in a non real-time environment and used to provide information as to why something happened and also can be predictive of what may happen. Generally, non-operational data is a measurement or detection of something other than operational data (e.g., other than measurements of parameters of the power used to operate a utility grid on a real-time basis). Non operational data is generally not collected through the SCADA system (although it could be) and is not collected in real time. Examples of non operational data include power line fault records (e.g. waveforms of the fault), equipment health information (e.g., transformer temperature, status of cooling fans, dissolved gas, etc.), power quality data, voltage disturbance data (e.g., voltage transients), harmonics, environmental data (e.g., lightning location and time, temperature, humidity, wind), and other system measurements that typically are not required on a constant basis in real time. Such non-operational data often is obtained by (and stored in) digital fault recorders, protective relay devices, dissolved gas monitors, temperature sensors and other sensing devices. While some non-operational data may result from a measurement of the same parameter as some operational data such as voltage and current, generally the non-operational data will be derived from a much higher sampling rate of that parameter (e.g., to identify harmonics) and/or may comprise a waveform of the parameter (e.g., as opposed to simply a rms value of the voltage or current). Processing the non-operational data can result in outages being restored faster, equipment being operated more efficiently, and decisions being made more accurately with respect to the reparation, upgrade, and/or replacement of power grid infrastructure.

Various non-operational data may be acquired and stored and then processed by one or more software objects. An open human machine interface may be implemented allowing various personnel in various settings to access these software objects according to various permissions and security prerequisites. In particular, various alarm conditions may be detected, and reports generated. The non-operational data may be acquired by various devices at various locations within a power distribution system, and communicated via any suitable manner.

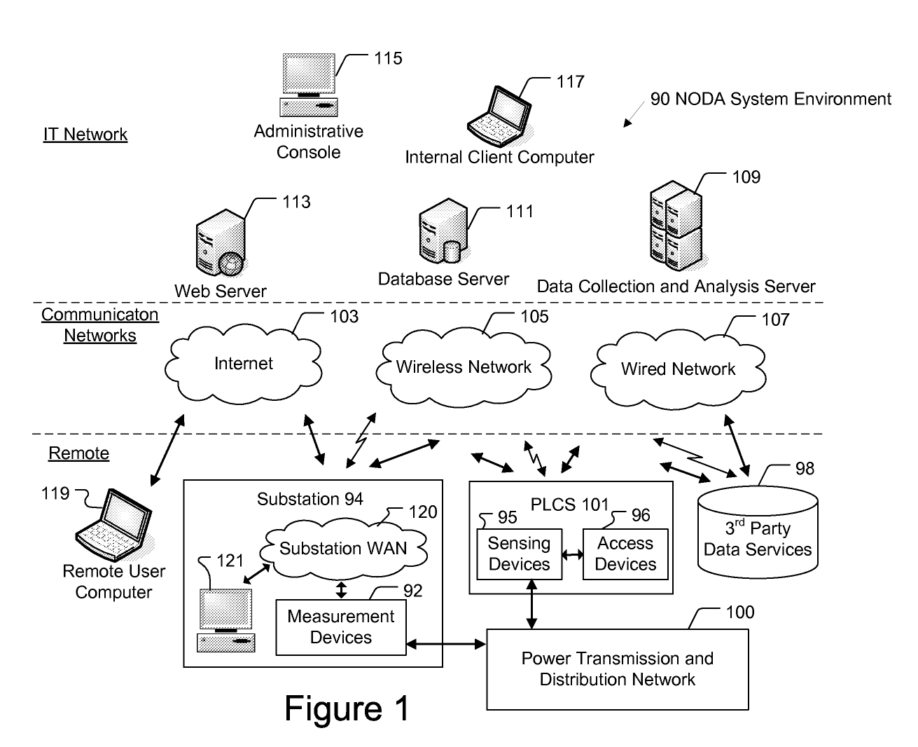

FIG. 1 depicts a NODA system environment 90. In an example embodiment, the NODA system acquires data from various measurement devices 92, such as intelligent electronic devices (IEDs), digital fault recorders, and power quality monitors located at power substations 94; from access devices 96 of a power line communication system (PLCS) 101; and from various data services 98. The various measurement devices 92 located at a substation may be coupled to a local area network or a wide area network 120. The access devices 96 may be located throughout a power grid 100 and may be coupled to various sensing devices 95 configured to obtain data, (e.g., non-operational data). The various data may be requested by or otherwise sent to a data collection and analysis server 109 using various protocols and transmission media, such as via one or more or the internet 103, a wireless network 105 (e.g., WiMAX, mobile telephone network, paging network), and a wired network 107. The collected data may stored in a database server 111. Various applications of the NODA system may be stored on and executed by the various servers 109-113, one or more administrative consoles 115, and internal client computers 117. Various firewalls and other security schemes may be implemented internally at the utility's information technology (IT) network and remotely at the various data sources. A web server 113 may provide web based access to remote user computers 119 and to the internal client computers 117 to allow such remote computers to access the various applications. In some embodiments a console 121 for running applications of the NODA system also may be installed at a substation 120.

Accordingly, the NODA system may obtain data of complex measurements using various sensing devices located throughout a portion of the power transmission and distribution network 100 controlled or operated by a given power utility company. Example measurements may include, although are not limited to, fault records, apparatus health data, power quality data, harmonics, and environmental data (e.g., lightning, temperature, humidity, wind). Various applications (e.g., analysis and reporting packages) may be executed to store and analyze the collected data. Various reports, graphs, charts, alarms, and task lists also may be generated.

In some embodiments, the network elements of a power line communication system may be used to collect and communicate the non-operational data. A detailed description of examples of power line communication systems 101, including access devices 96 such as bridges, backhaul points, repeaters, along with related devices such power line servers, sensing devices 95, and other components and their functionality are provided in U.S. Pat. No. 7,224,272, issued May 29, 2007, entitled “Power Line Repeater System and Method,” which is hereby incorporated by reference in its entirety. Additional descriptions of such systems, devices, sensors, components and their functionality also is provided in U.S. patent application Ser. No. 11/423,206 filed Jun. 9, 2006, entitled “Power Line Communication Device and Method,” which is hereby incorporated by reference in its entirety.

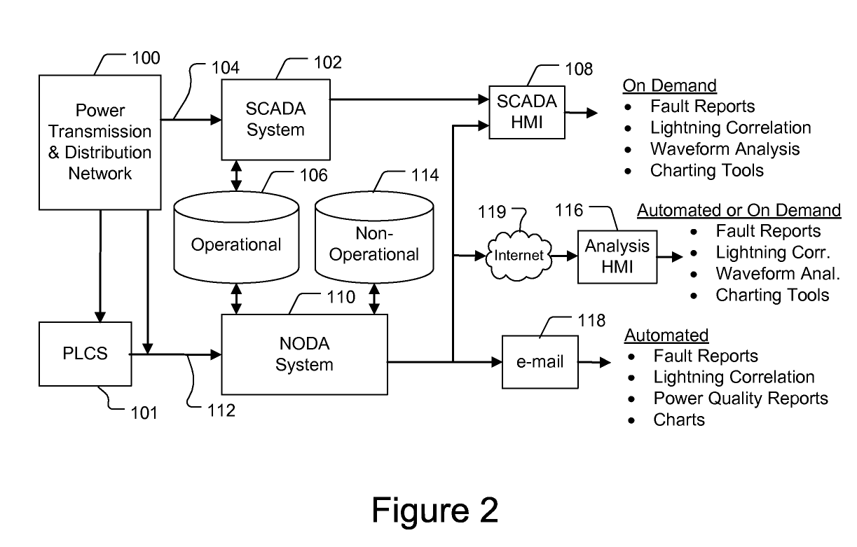

FIG. 2 shows the relationship between a SCADA system 102 and a NODA system 110, according to an exemplary embodiment of the present invention. The SCADA system 102 may continuously collect a plurality of data either directly or via a remote terminal unit (RTU) to obtain operational data 104 from one or more substations 94 of a power distribution network 100. The operational data 104 may be stored in an operational data database 106. A human machine interface (HMI) 108 may allow such data to be displayed in real-time in charts, graphs, tables or other formats.

In one embodiment operational data such as the real time circuit voltages, amperages, watts, and VARs are collected by the SCADA system 102 or the like at each substation, along with the status of circuit breakers at the various substations and the power factor directly derived from the collected data. Typically such data is collected every 3-5 seconds by the SCADA system. The operational data typically is accessed using a given substation's remote terminal unit (RTU). Such RTUs often have direct analog inputs (4-20 mA or 0-10 volts) from circuit potential transformers and current transformers and direct digital inputs from breaker auxiliary contacts. More modern substations may include substation computer gateways that access the voltages, currents, and status digitally from computer relays. The SCADA system 102 typically gets the real time operational data from the RTUs or gateways via a standard protocol, e.g. DNP3. The format of the data may be, for example, a value and a node number.

The NODA system 110 may receive non-operational data 112 of a power transmission and distribution network 100 (such as from a PLCS 101) and store the non-operational data 112 in a non-operational data database 114. The NODA system 110 also may access the operational data database 106 to store and/or retrieve data as needed. To integrate with the SCADA system 102, the NODA system 110 may be deployed as a centralized system either making use of the SCADA HMI 108 or another HMI 116. By working complementary to the SCADA system 102, the NODA system 110 may provide a variety of desirable functions not performed by the SCADA system 102. For example, unlike the SCADA system 102 that just passes the collected data through (without significant processing), the NODA system 110 may continually process collected information, automatically diagnose a broad collection of transmission and distribution issues, and generate alarms based on user configurable conditions. The NODA system 110 also may provide action-oriented, “value event” reports. A value event may be a time and/or money saving activity or an improvement in reliability that can be performed by the utility that is based on insights revealed from the acquisition and analysis of the non-operational data (e.g., in conjunction with the operational data). The value event reports may be delivered to the appropriate utility engineers via e-mail 118 or the HMI 116. Accordingly, some information may be reported on demand through the SCADA HMI 108 and the NODA HMI 116. For example, a failing transformer may be identified and the analyses automatically integrated with the utility's asset/work management system. Thus, the value event analysis may be automatically “served” to another IT system.

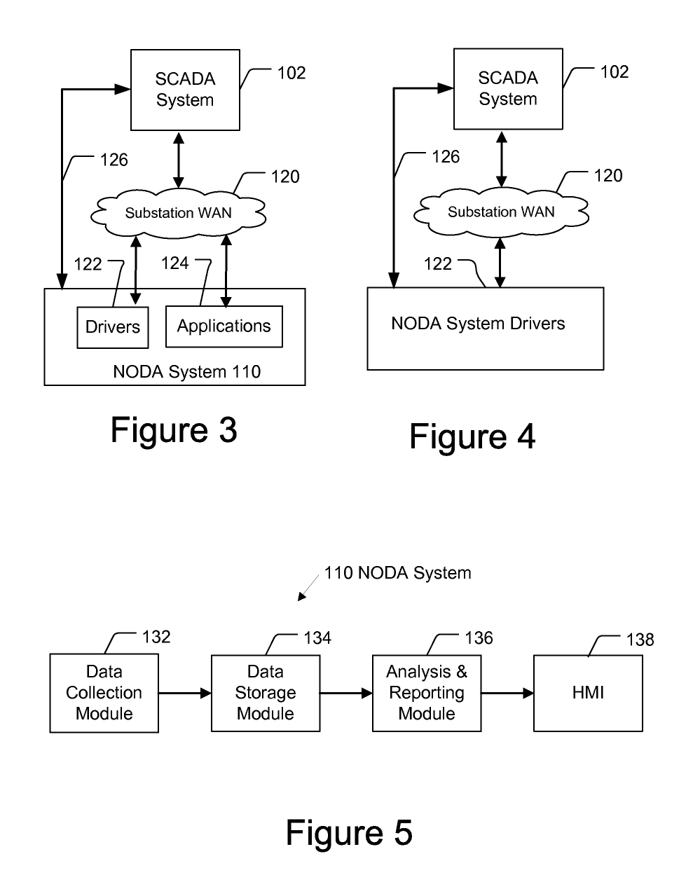

FIGS. 3 and 4 show example configurations for integrating the SCADA system 102 and NODA system 110 at a power system substation 94. The SCADA system 102 and NODA system 110 may be coupled to a wide area network 120 at the substation 94 or suitable local area network (LAN). In the configuration shown in FIG. 3, both the drivers 122 and applications 124 of the NODA system 110 may be installed on a computer located at the substation 94. In another configuration as shown in FIG. 4, the drivers 122 are installed on a computer located at the substation, while the available application programs of the NODA system 110 are located at some remote location (e.g., a utility company's command and control center). In some embodiments, the NODA system 110 may be integrated with the SCADA system 102 at multiple substations. In other embodiments, SCADA data from all substations may be accessed by the NODA system from a given substation. In still another embodiment, the NODA system 110 may be located at a central command and control site and communicate with the SCADA system 102 at one or more substations. Within a substation the NODA system 110 or a component thereof may access the SCADA system 102 via phone lines 126 or through the WAN 120 or suitable local area network (LAN).

By deploying all or a portion of the NODA system 110 at a substation, several benefits may be realized. One benefit relates to data filtering. Non operational data must be managed, which in some cases includes filtering the data. For example, a fault may result in a number of intelligent electronic devices (IED's) in the substation capturing essentially the same fault data. A local analysis system can determine which data is redundant and only transmit and store the fault data once. The intelligent filtering of data becomes more valuable as the number of IEDs in a substation increases. Another benefit is that analysis and reports may be generated more quickly when the analysis system is local to a substation whose data is being analyzed. Still another benefit relates to data security. All data in the substation, both operational and non operational can be collected and pushed up to a central data server avoiding the need for users to download data using proprietary software using various communication paths. In addition, the NODA system 110 may more readily control substation automation equipment when located at the substation 94.

### Non-Operational Data Acquisition (NODA) System

FIG. 5 depicts the high-level functional modules of an NODA system 110, according to an example embodiment of the present invention. The non-operational data acquisition (NODA) system 110 may include a data collection module 132, a data storage module 134, an analysis and reporting module 136, and a human machine interface module 138. In one embodiment, the NODA system 110 may be a scalable, self-healing system implemented as a Windows application (or other OS application) utilizing any database, such as SQL Server, to store measurement data including waveform, historical trend logs, and apparatus analog events (which is data related to the operation and health of the apparatus (breakers, transformers, capacitors, circuits, etc.—rather than power measurement data—and includes digital event data regarding the operation of the equipment and analog data such as temperature, pressure, gases, oil levels, and internal motor values). In addition, the NODA system 110 may be web enabled, allowing utility engineers to have immediate Internet access to high-level reports as well as raw measurement data. For example, a library of drivers may be included to collect data directly from a broad range of substation data collection devices, including IEDs, relays, digital fault recorders, substation power monitors, apparatus monitoring devices, and power quality monitors. In some instances, the drivers may form part of a database adaptor wherein each adaptor that includes a driver and API.

In some embodiments, the NODA system 110 may be a database-driven system in which key modules, such as data collection and data analysis, are managed or controlled by information in a database. The system database, for example, may include tables with lists of data collection, analysis, and reporting jobs. NODA system components may query the database to obtain the next job to execute, remove the job from the list, then attempt to accomplish the job with a separate process. If the process fails to accomplish the job, the job may be put back on the list. This allows the NODA system modules 132-138 to be installed on multiple computers, resulting in the modules “competing for jobs.” In this way the NODA system 110 may automatically perform load leveling. As monitoring devices are added, new servers can be added to maintain the speed and performance of the system. Such an architecture may allow the NODA system 110 to be self-healing, such that if one server is lost, the other servers in the system handle the load. For systems that communicate via phone lines, a Digiboard system may be employed in which one data collection server can drive up to sixteen modems via serial ports. The result is a load-leveling, self-healing system that scales automatically as the monitoring or analysis needs of the utility change.

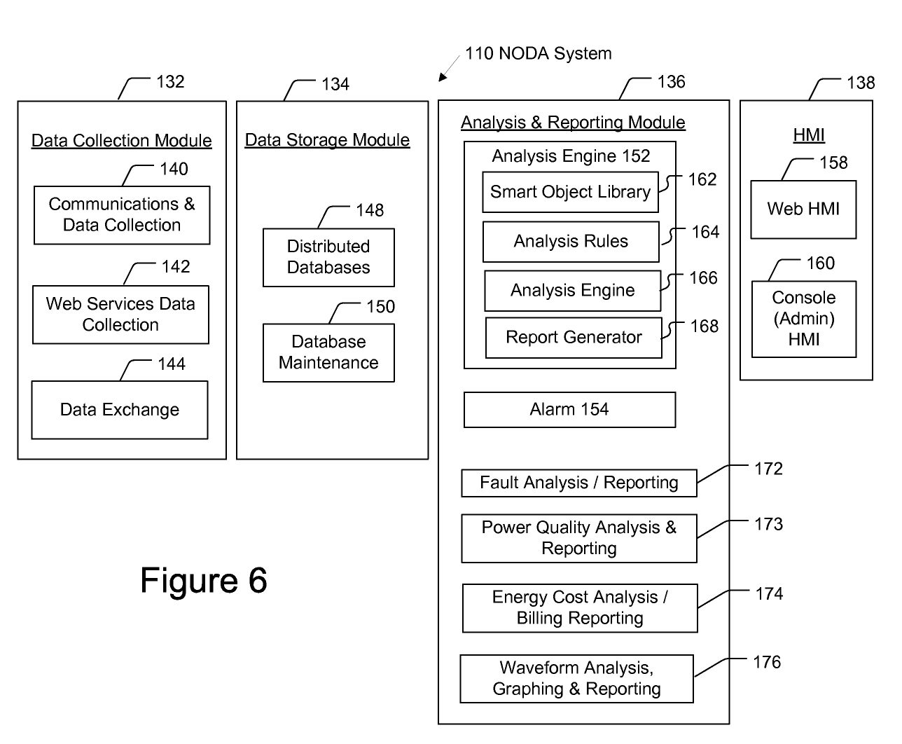

FIG. 6 shows various components of the NODA system 110 organized according to the corresponding high-level modules described above. The data collection module 132 may include various components, categorized as a communications and data collection component 140, a web services data collection component 142, and a data exchange component 144. The data storage module 134 may include one or more distributed database components 148, and a database maintenance component 150. The analysis and reporting module 136 may include an analysis engine component 152, an alarm component 154, and an analysis and reporting components 172-176. The analysis engine component 152 may include a smart object library 162, analysis rules 164, an analysis engine 166, and a report generator 168. The analysis and reporting components may include a fault analysis and reporting module 172, a power quality analysis and reporting module 173, an energy cost analysis and billing report module 174, and a waveform analysis, graphing and reporting module 176. The human machine interface module 138 may include a web-base human machine interface 158 and a console (administrative) human machine interface 160. The various modules 132-138 are described in more detail below.

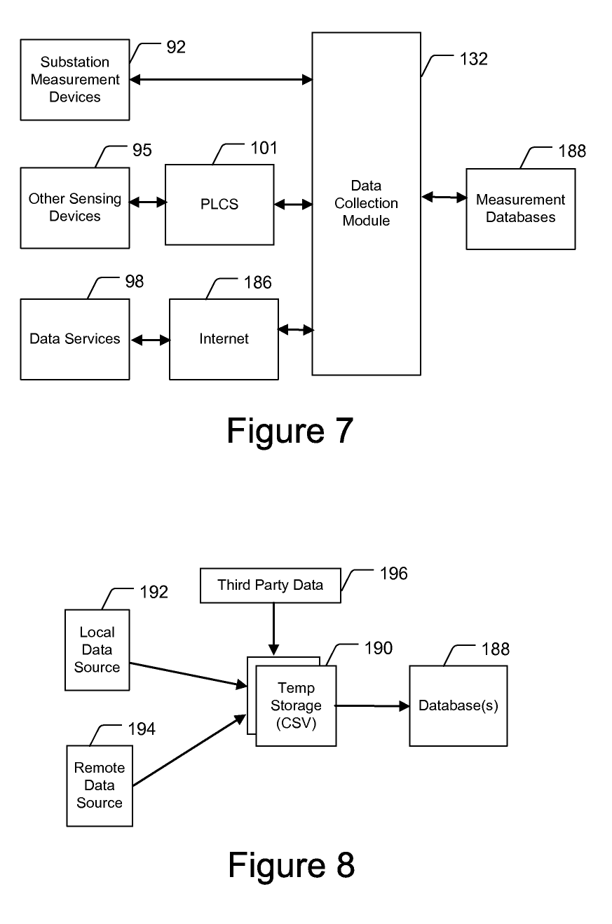

FIG. 7 shows the various data paths of the data collection module 132. The data collection module 132 collects at least non-operational data, such as, for example purposes only, from measurement devices 92 in a local substation (of the power transmission and distribution network 100), from other sensing devices 95 via a PLCS 101, and/or from various data services 98 via an IP network, such as the internet 103. Various protocols may be used such as a serial protocol, a wireless protocol, an internet protocol, or another protocol. The collected data may be stored in measurement databases 188, which may be part of the distributed databases 148 of the data storage module 134.

Substation measurement devices 92 may comprise intelligent electronic devices (IEDs), substation power monitors, power quality monitors, apparatus condition monitors and sensors, and digital fault recorders may be located at the substation and be the source of collected data. Other sensing device may comprise utility meters at customer premises and sensing devices accessed by network elements of a PLCS 101, which also may be the source of collected data. Data services 98 may comprise weather information, lightening strike data, and other data from various data service organizations, which may be another source of collected data. In cases where a substation data concentrator is present, the data collection module 132 may collect and upload data stored in the concentrator to a central data warehouse, and connect directly to substation devices that hold the more complex data that is not collected by the concentrator.

In an example embodiment, the data collection module 132 is an encapsulated Windows application that may be used from a central computer to poll each device in the NODA system 110. Alternately, it can be installed on a PC at the substation to collect all data in the substation via a serial connection or the substation internal network and then transfer the data to the central office data warehouse.

While substation measurement devices usually allow operational data to be collected using standard industry protocols such as Modbus or DNP3, non-operational data stored in these devices may be communicated via these or other protocols. For example various drivers may be included in the data collection module 132 to collect non-operational data from a broad array of monitoring devices. A given device driver typically may serve four functions. The first function is to connect to a corresponding device using that device's communication and command protocol. The second is to collect raw data. A third function is to validate data and perform basic error checking. A fourth function may be to translate the data into a comma-separated, variable format (CSV) (or other suitable tabular file format) for temporary storage. The temporary file format or “transfer file format” can be published so that third parties can collect non operational data, store that data in the file transfer format and the system would be able to automatically take that data and import it into the non operational data base thereby making the system more open.

FIG. 8 depicts the various sources of CSV files 190. Data may be obtained locally from data sources 192 (e.g., in the substation) or remotely from data sources 194 (e.g., a PLCS). Further, data may be obtained from third party sources 196. The NODA system 110 may import the CSV files 190 immediately, on demand, or at periodic intervals into the measurement database(s) 188. In some cases the files may be sent via FTP, or other protocol, to a remote central warehouse for storage. This intermediate CSV file step allows third-party systems to make their data available to be imported seamlessly by the NODA system 110 without the need for custom integration. Typically, a driver will download all data from its corresponding device(s). Data can be stored as complex waveform tables, historical trending logs, event or status logs, and device-specific logs including flicker and power quality logs.

The communications and data collection component 140 (see FIG. 6) of the data collection module 132 includes the drivers for collecting data from devices at the local substation and from devices coupled to the PLCS 101. In some embodiments, the data collection module 132 is installed at a central location from where it polls substation devices via communication links (e.g., TCP or other protocol) provided by fiber, a dedicated phone line, wirelessly, or a shared phone line. Device-initiated uploads also may be performed. In other embodiments the data collection module 132 is installed at each substation, and collects local data, stores it, and transfers at least some of that data to a central data warehouse. For example, the data collection module 132 may be used in conjunction with existing substation data collection systems (e.g., SCADA system) where a substation data concentrator or RTU is deployed.

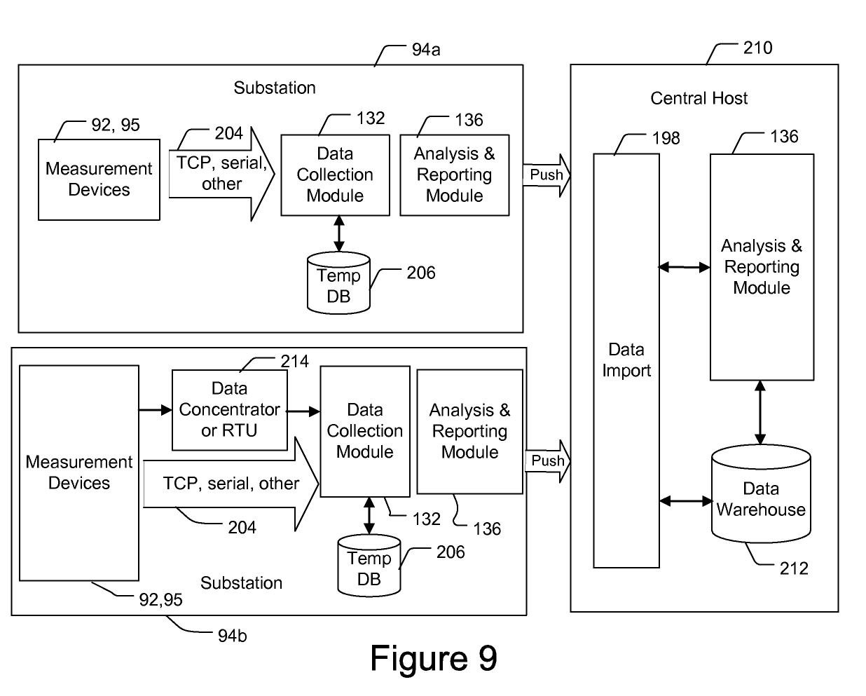

FIG. 9 shows various data collection configurations. Within substations that connect measurement devices to a LAN (or WAN), the most effective data collection method may be to allow fast and easy access by the central polling device. Low-cost, third-party, serial-to-TCP converter devices also may be used to integrate serial devices. The data collection module 132 may directly access measurement devices or access data through a data concentrator. For example, the communications and data collection component 140 may access data using Schweitzer relays through a Schweitzer model 2020.

At a first substation 94a, the data collection module 132 may collect data from measurement devices 92 or sensing devices 95 via TCP, serial, wireless, frame relay, modem or other communication links. The data may be stored in a temporary database 206. Data analysis and reporting may be performed from a central host 210. For example, data from the substation 94a may be accessed by a locally installed analysis and reporting module 136 and pushed to the central host 210. A data import component 198 may pass the data to the analysis and reporting module 136 and/or store the data in a data warehouse 212.

In some embodiments a data concentrator may be used. For example at a substation 94b a data concentrator or RTU 214 may collect data from substation measurement devices 92 and sensing devices 95. Such data may be accessed by the data collection module 132 from the data concentrator or RTU 214 (or directly) and pushed to the data warehouse 212 at the central host 210 by a data compression and encryption module. To maximize the value of the data and especially for correlating data from different data sources, time and data synchronization of system equipment is desirable. GPS or IRIGB (Inter-range Instrumentation Group, standard B) are the examples of synchronization systems that may be used.

The web services data collection component 142 (see FIG. 6) implements web-based data collection schemes. For example, data may be collected from a third-party supplier of information or directly from Web-enabled devices. Web data sources may include Vaisala's Lightning Detection Network and ISO's real-time pricing information. The web services data collection component 142 may be a self-contained software component that acts independently from the data collection module 132 and may collect data from the Web source continuously on a polling basis or when an event occurs. An example of the latter is a detected fault upon which an online data feed may be queried to determine if a lightning strike occurred at the time and location of an identified fault. This information would then be correlated to the time of the fault and appear in a fault report.

The data exchange component 144 (see FIG. 6) performs an integration function that includes the transfer of data between the NODA system 110 and a related utility system, such as an outage or asset management system. This information exchange makes each system more powerful. The correlation of data from different systems imparts greater insight in identifying and solving problems. Example embodiments of the data exchange component 144 may be integrated to collect measurement data from Square D's SMS system, General Electric's PMCS, and Power Measurement's ION Enterprise systems. Further, the NODA system 110 may be integrated with SCADA systems to determine when a fault occurred. In such case the NODA system 110 may initiate an immediate download of fault data from substations where low-speed telephone lines preclude continuous polling of devices. Using the data exchange component 144, information can be transferred to other IT systems to increase their value, such as supplying asset condition measurement data to an asset management system or outage events to an outage management system.

In some embodiments the data exchange component 144 includes a data acquisition “service” that continuously or upon certain conditions acquires data from a utility company's information technology (IT) system. This is usually performed through the IT system's data transfer interface. For example, an Application Program Interface (API) may be included (in the data exchange component 144 of the remote IT system) to enable data communications with third-party IT systems. The API not only provides a stable and supported method for obtaining data but also provides functions that support a limited amount of data analysis, which can save time and expense in integration. Such analysis may include “bucketing” power data in intervals for energy and demand analysis as well as enumerating voltage sags from waveform events. Generally, a database API provides back the data that is in the database. However, many application that want to use the data may have specific requirements such as using energy usage data to prepare bills and correlate with market purchases. These applications generally want energy data “bucketed” such as, for example, in five minute averages rather than just raw energy data that would be arbitrarily collected and time stamped. The benefit here is that the system can “prepare” the data the way application needs to use it, thereby avoiding work at their end and making the system more valuable. In a given embodiment the API may provide more than one hundred functions. An API also may be included which may be used for data access by the analysis and reporting module 136, as well as by third-party applications. Many functions may be COM objects usable by C++ as well as by scripting languages such as ASP and Visual Basic. Other objects may be only available to C++ applications. The data exchange component 144 may allow data to be exported in a variety of formats, such as COMTRADE, PQDIF, a simple comma separated variable format and various other formats.

### Data Storage Module 134:

As depicted in FIG. 6, the data storage module 134 includes various components. The data storage module 134 (see FIG. 6) includes the database component(s) 148 for the storage of measurement and system data. All measurement data is stored in one or more databases, which may be physically distributed (not co-located). In an example embodiment SQL Server is used, although other databases may be implemented. The database schema enables the storage of any and all measurement data regardless of the sampling rate or measurement parameter. In addition, the granularity or precision of the original data collected by the device may be retained. The database stores additional information beyond measurement data including “node” properties and connectivity information. This additional information may be used by the analysis and reporting module 136 to make productive use of the data. The relationship fields allow for parent/child paradigms (containers) as well as electrical upstream/downstream paradigms (connectivity data). Node property fields include but are not limited to node location (longitude/latitude), firmware version numbers, and thresholds (e.g., voltage and current high and low threshold used to generate alarms). A system database includes a set of tables that identify all measurement devices in the system, their database locations, alarms, and scheduled download and analysis jobs.

The distributed database implementation allows the user to set up multiple databases. For example, all databases may be on a local-area network (LAN) or wide-area network (WAN). Therefore, a user may set up a database in each substation, which would be transparent to the HMI. The user may also use multiple database engines. For example, one district's data may be stored in an Microsoft® SQL Server database, while another district's data may be stored using Microsoft® Office Access.

Data may be exported in various formats, such as comma-separated variable format via the data exchange module 144 of the data collection module (DCM). In some embodiments waveform data may be exported in the IEEE defined COMTRADE and PQDIF formats. The system's Application Program Interface (API) (e.g., of the data exchange module 144) may be used to automate export tasks. This gives users and third-parties easy access to the database for robust application development that would be unaffected when the database schema changes.

The database maintenance component 150 provides tool for maintaining the databases 148. Users can back-up the full database as well as archive and trim portions of the database with corresponding restore functions.

### Analysis and Reporting Module 136:

As illustrated in FIG. 6, the analysis and reporting module 136 used to reconfigure and modify the power distribution system 100 and may include several components including an analysis engine component 152, an alarm component 154, and one or more analysis and reporting modules. In particular specific conditions can be identified and associated responsive tasks identified to provide a cost saving and/or improvement of reliability.

Following are examples of some analysis and reporting modules, although other modules also may be included.

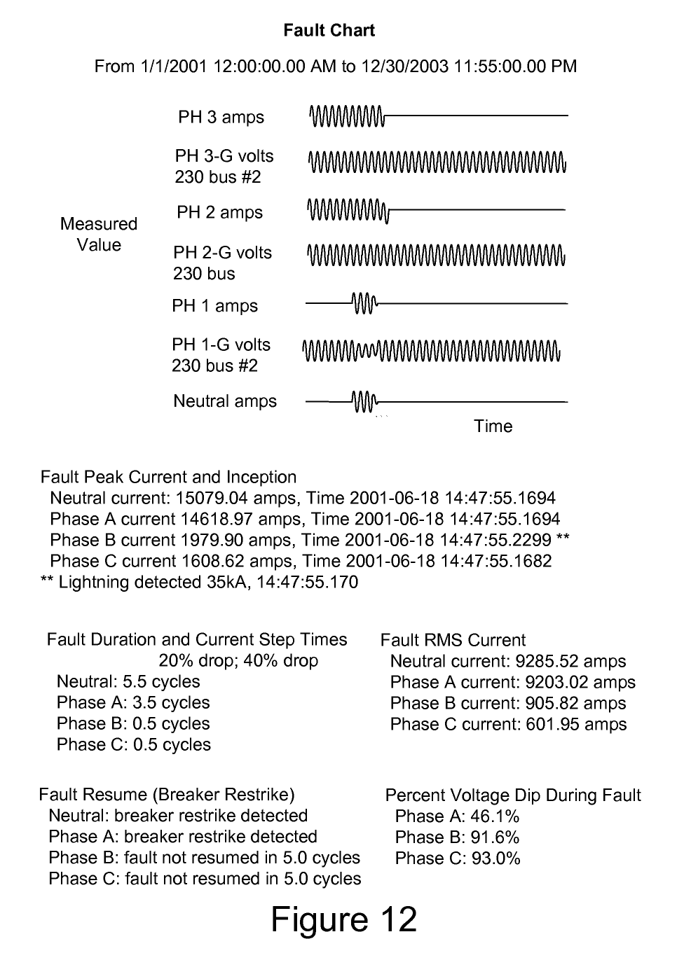

A fault analysis and reporting module 172 automates the fault reporting function and may include ancillary analyses such as lightning fault correlation. The utility will want to know when a fault is due to a lightning strike and if so, they may dispatch a crew to find the damage. The utility can also use the information to determine the effectiveness of its lightening arrestors. Another analysis may include breaker re-strike detection. When a breaker operates, the contacts open extinguishing the arc and associated current flow. However, if the oil in the breaker is contaminated or the contacts are severely pitted a re-arc can occur quickly for a cycle or two. This is a precursor to a complete breaker failure. This system can provide this information to the utility so it can take appropriate action. Another analysis may include the impact of a lightening strike to power quality impact (i.e., compatibly of the delivered power to the needs of the customers load.) Typically voltage fluctuations resulting from a lightening strike may cause sub-cycle high frequency voltage transients that can cause miss firing or under or over rms voltage. The fault analysis and reporting module 172 provides functionality beyond a conventional oscillographic report produced by digital fault recorder software packages by supplying additional analytical computations and diagnoses. An example fault report is shown in FIG. 12. The fault analysis and reporting module 172 may generate reports that include:
Precise inception time of the fault to the maximum data-point resolution provided by the recorder
Inception time of the fault correlated to lightning events on the circuit (such as from Vaisala feed)
Breaker re-striking detection time and location
Precise fault duration, peak current, and peak RMS current
Current step durations describing remote-end clearing
Voltage sags per phase showing impact on power quality
Waveforms of the beginning and end of the fault (voltage and current)
Equipment that change state (e.g., reclosers, switches, etc.)
Ancillary IED-supplied information including fault location and type

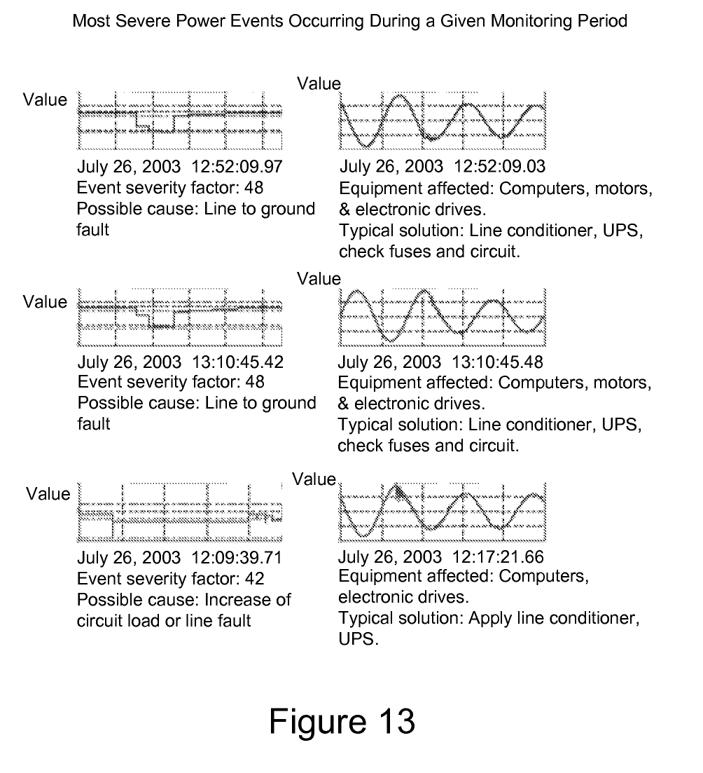

A power quality analysis and reporting module 173 provides intelligent analysis of power quality disturbances along with the impact on the customer and the origin of the disturbance. For example, the power quality analysis and reporting module 173 generates reports of the power quality during a particular disturbance or over a given time period. The most destructive power quality events may be highlighted with pertinent information such as: potential destructive impact on sensitive electronic loads; the direction of the source of the disturbance as upstream or downstream from the monitoring location; the specific source of the disturbance (if known); the equipment it may have (or did) affected; and an industry-accepted solution to the problem. In addition, summary analyses of harmonics, zero-crossing errors, and notches may be presented. For example, some customer loads are synchronized to the zero crossing of the voltage waveform of the delivered power. If the voltage waveform is distorted the waveform can have multiple zero crossings or be time shifted affecting the operation of the phase controlled load. As another example, a phase controlled rectifier may have its power control device (thyristors, power transistors, etc) “turn on” or conduct at the 60 degree point on the voltage wave. If a large notch occurs the thyristor may not turn on or not supply enough energy to power the load. In an example embodiment, the report is generated as a PDF or RTF file, and e-mailed automatically and/or made available via the Web HMI 158 or console HMI 160. FIG. 13 shows a portion of an example power quality report, that includes the most sever power events that occurred during a given monitoring period. For each reported event there is a chart on the left showing an expanded portion of a given voltage channel's RMS time plot during the event; and a chart on the right showing more details of the event.

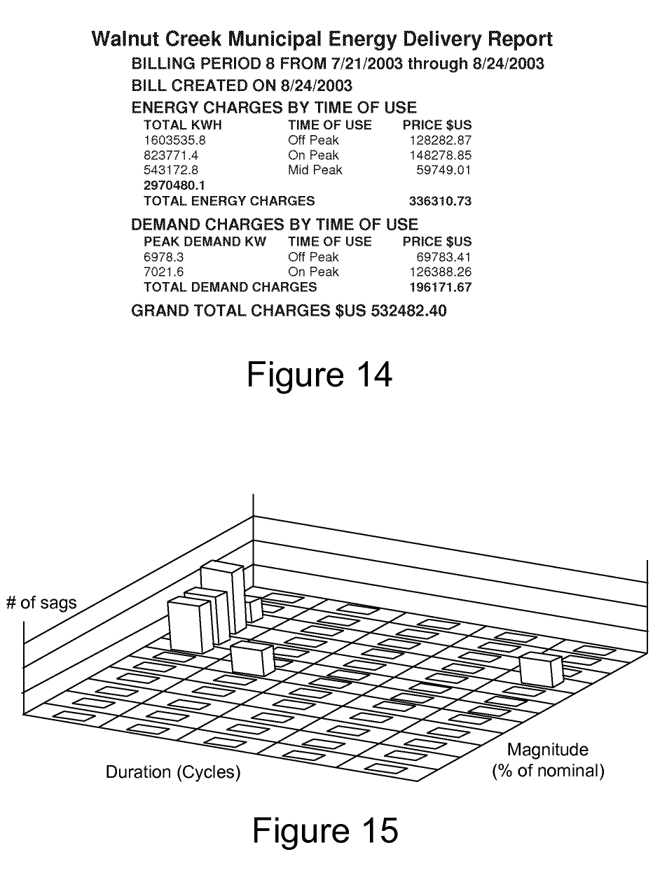

An energy cost analysis and billing module 174 includes a rate interface for the analysis and billing of power distributed to member utilities or to power customers. In one embodiment, a web interface is provided to allow power customers to view up-to-the-minute (real time) energy usage and costs. In addition, the energy cost analysis and billing report package 174 may generate a bill for a specific customer. FIG. 14 shows an example billing report that may be generated.

A waveform analysis, graphing, and reporting module 176 is a comprehensive set of tools for diagnosing more complex transmission and distribution network problems and performance, and for reducing costs. In some embodiments the report content, the format, and the delivery can be configured to allow utilities to customize the analysis and reporting modules to meet the specific needs of the distribution network. This module allows the user to process large amounts of waveforms (e.g., hundreds or thousands) looking for events of interest. The module includes automated waveform functions build into the other modules such as the power quality module. The collection of functions process the waveforms into its harmonics, impedance, phasors, sag frequency, CBEMA/ITIC, and harmonic frequency distribution by a click of the mouse. This functionality is largely independent of the structure of the waveform data.

The waveform analysis, graphing, and reporting module 176 may provide two methods for manual data charting and manipulation, both of which may be available via the Web HMI 158 and console HMI 160. One method may be used to create static charts and graphs, while another method may provide a more advanced, interactive method for manual data analysis. The charting and graphing package may be used on data independent of the measuring device, so as to provide charting and graphing for all available power measuring devices available today as well as those that may be introduced in the future. The module 176 also may provide for plotting and charting data that is unrelated to power monitors such as analog data (temperature, wind, and even security (access) information, etc.) and binary information (breaker open/closed).

In an example embodiment a user may select from various static charts and graphs. For basic charts the user selects the chart type, monitoring asset, and time range. For comparison charts the user selects the monitoring asset and the time interval of the comparison. FIG. 15 depicts an example static chart.

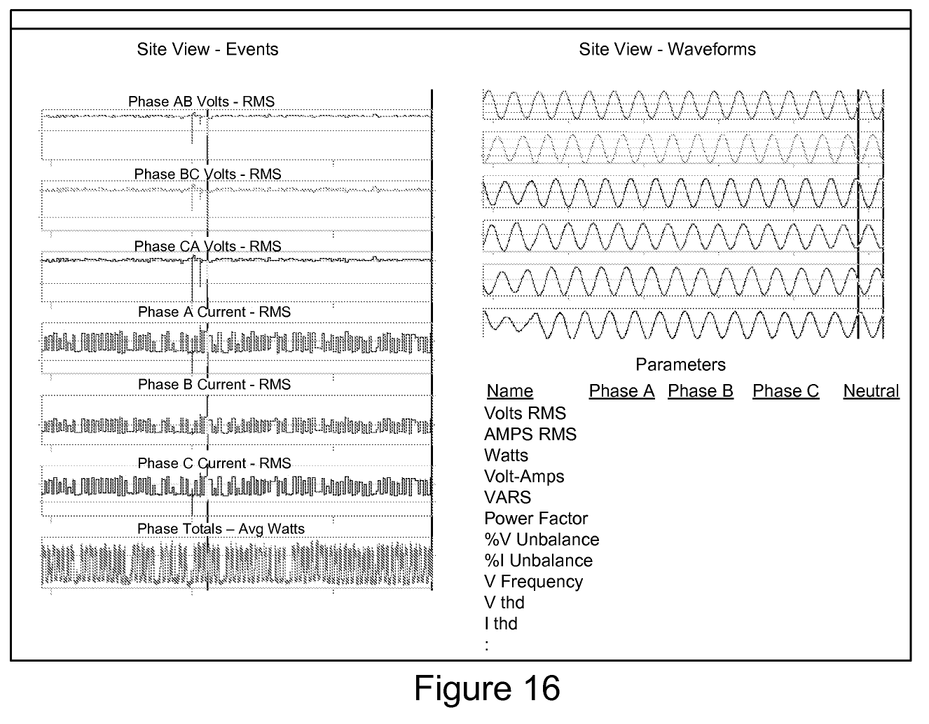

In another embodiment an interactive graphical interface may be included from which to view the archived data in both waveform and tabular form. Multiple waveform events representing a continuous waveform may be appended and displayed as a single, multi-cycle waveform event. For example, a large collection of summary graphs including sag frequency, harmonic distribution, ITIC, CBEMA, and time plots may be included. Users can enlarge these summary charts with a click of the mouse, displaying a detailed event of interest such as a waveform, phasor, harmonic distribution, or other parameter. Extensive calculations may be computed from waveform and analog data in real time as the user surveys data parameters such as W, VA, VARS, THD, V or unbalance, Vrms, Arms, PF, and a single harmonic. Channels from multiple dissimilar devices can be viewed and charted simultaneously in the same window. This flexibility is invaluable when comparing a similar power event recorded by different measurement devices on the circuit. FIG. 16 shows an example view of a few interactive charts and graphs.

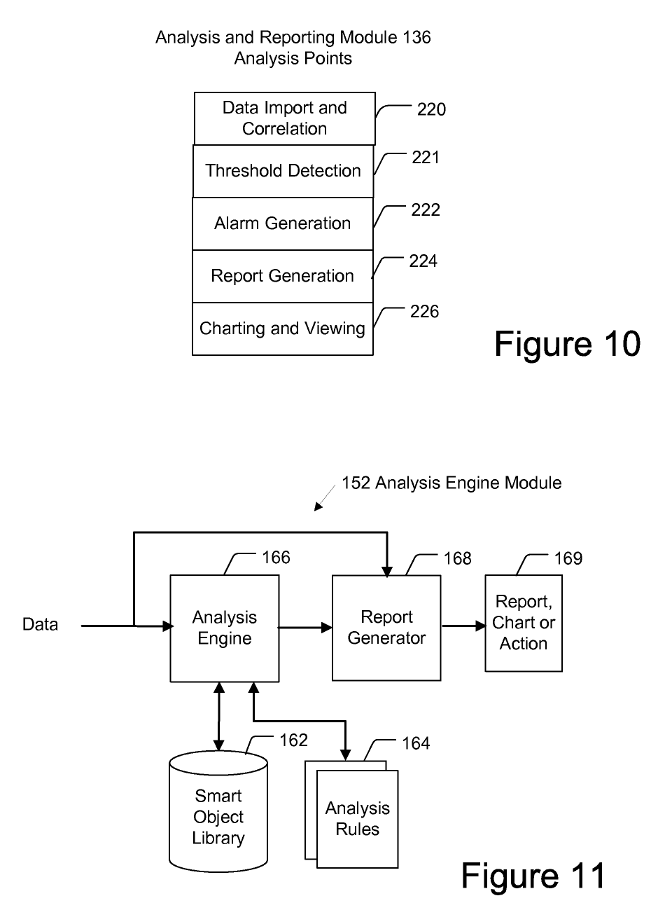

Data analysis may be performed at various stages of the information path. FIG. 10 depicts various functions during which data analysis may be performed, including during data import and acquisition 220, during threshold detection 221, during alarm generation 222, during report generation 224, and during charting and viewing 226. When data is imported and correlated, data may be processed to detect one or more conditions (e.g., threshold exceeded), and one or more analytical processes may be made on the streaming analog (e.g., real time operational data collected every few seconds) and waveform data. Specialized analyses may occur automatically when a condition, such as threshold exceeded, is detected and an alarm is generated. An example is processing to determine the origin (e.g., upstream or downstream in the power grid relative to the measuring device(s)) of a power disturbance when a voltage fluctuation is detected. Data analysis also may occur when a periodic report is automatically generated or in response to a user request to generate the report. Thus, the report is generated on the most recent received (or the freshest data collectible). Real-time analyses may occur as the user manually interacts with the data. An example is an engineer using waveforms captured during a circuit fault and having the software convert the waveforms in real time to phasors, harmonics and impedances, and being able to step through the fault to better identify the cause and system response. Such analyses often involve the correlation of data from multiple sources and advanced expert analysis. An example is the impact of a fault on a substation transformer. Immediately after the fault, harmful dissolved gases increase in the transformer oil, but typically dissipate unless there is some significant damage to the transformer. The user can access the fault and dissolved gases data (via one application) obtain real time gas analytics (Rogers Ratio for example), determine the severity of the fault (in terms of fault current and its “I2T” (current squared multiplied by time equating to the energy), and observe the impact in order to identify a transformer problem.)

Referring again to FIG. 6, to provide versatility, a generic analysis engine component 152 may be used to develop and execute specific analysis application algorithms, which allows for rapid development and customization of applications in response to identifiable needs. FIGS. 6 and 11 depict the portions of the analysis engine component 152, including a smart Object Library 162, rules 164, an analysis engine module 166, and a report generator 168. The analysis engine module 166 controls the execution of one or more analysis rules 164, which includes calling one or more smart objects from the object library 162 to process data. More specifically, the “rule” is created by a subject matter expert (SME) module. The SME has a list of all the Smart Objects supported by the system and then links them together in the script. The smart Objects comprise an extensive library of domain specific utility objects. The Smart Objects know what data is needed to perform the function and uses the Data Interface Service to retrieve the data. In some cases all or none of the required data may be available, in which case the Smart Object will provide minimal analysis or no analysis The report generator 168 generates a report, chart or action 169 from the analysis results.

The smart object library 162 is a group of software objects (e.g., COM, .NET assemblies, DLLs, etc.) that encapsulate analysis methods and are available to other components of the analysis engine 152. Each object is designed to perform a specific function or analytical procedure. An example of a simple smart object is the computing of power factor from recorded kW and kVAR values, while a more complex smart object is a neural network based capacitor signature analysis of a voltage waveform. Given waveform (oscillography) data collected from devices (nodes on the grid) these, more complex, reusable smart objects, using a combination of SME developed rules-based expert systems and SME developed fuzzy logic systems can analyze the waveform data to detect the following occurrences:
Waveform Signature Analyses.
   Power factor capacitor—Signature analysis of voltage waveform to identify the transient, followed by a surge that is typical of the operation of a power factor capacitor.
   Bridge rectifier—Signature analysis of a voltage waveform to identify phase synchronized notches typical of a three phase bridge rectifier.
   Arcing fault—Signature analysis of voltage waveform to identify a cluster of transients according during a fault that is typical of an arcing fault
   Breaker re-strike
Waveform Expert and Fuzzy Analyses
   Line to ground fault—Identify when the line to line voltage drops to line to ground potential during a fault
   Fuse Clearing Fault Current—Signature analysis of the voltage waveform to identify a voltage arc proceeding fault current followed by the loss of voltage if downstream of the fuse or the return of normal voltage if the measurement is made upstream of the fuse.
   Fault origin Upstream/downstream—Expert system to identify the if the fault current is upstream or downstream of the measurement point by correlating the voltage drop due to the fault and whether a sharp increase of current correlated with the voltage drop
   Rotating load start up—Signature analysis of the current waveform or if current is not available the voltage waveform to identify the start up characteristics of a rotating load to identify the start up of a motor.
   Power quality event severity—Fuzzy based system that correlates the characteristics of the power quality event (sags, outages and transients per IEEE 1159) to determine the relative impact or harm to a sensitive customer computer based load
   Resonance—Signature analysis of the voltage and current waveform to identify the operation of a capacitor and to correlate that event with a surge of current at a precise point of the waveform
   Insulator arcing—Signature analysis of the voltage and current waveform to identify a fairly long half cycle transient on the point of the waveform that is indicative of a dielectric breakdown.
   Insulation breakdown (water egress)—Similar to the “insulator arcing” but focused on underground circuits
   Arc extinction—Analysis of the voltage waveform to determine the precise point the arc was extinguished often used to identify the I2T the arc across breaker contacts
   Voltage transient origin (direction)—Waveform signature analysis of voltage and current waveforms that compute the net positive or negative energy flow associated with a transient to determine whether it occurred upstream or downstream of the monitoring location

A group of simpler, reusable smart objects, also working on the waveform data can perform complex calculations, branching logic, Boolean tests, and are not based on expert or fuzzy logic systems (unlike those above).
Waveform Computations
   Fault inception—Detect actual fault inception by examining the waveform to determine, to the accuracy of the sampling rate, exactly when the fault started.
   Breaker re-strike—Using the collected waveform data captured during a breaker operation, determine if a breaker re-strike (arcing) occurred
   Fault impact on transformers and breakers (I2R)—Calculate, using the sampled waveform data the total energy of the fault current.
   Remote clearing times—Using waveform data from multiple devices calculate remote clearing times.
   Impedance—Using current and voltage waveform data calculate fault impedance.
Analysis Logic
   Fault identification (lightning, other)—Using externally accessed data in combination with available smart objects to determine correlation, if any, with other events and the fault using time and location parameters.
   Fault clearing analysis (preliminary)—Using waveform data and user supplied thresholds determine if the fault was cleared correctly.
   IEEE 519 harmonic analyses—Test for harmonic limit compliance using the IEEE 519 standard.
Energy cost (full rate schedule interface)—Using user supplied rate schedule and captured voltage, current, and or wattage data calculate energy costs

The analysis rules 164 define the analysis to be performed, the smart objects to be used, and the information to be generated (i.e., the output). The rules defines the objects to use and it is the analysis engine that processes the rules. So the objects get the data and include the embedded algorithms. The engine processes the objects in the order of the analysis rules code and allows the results of one object to pass to another. The engine is then able to use the report and notification systems based upon the results of the overall analyses.

The analysis engine 166 executes the analysis rules 164 (program code), which links the smart objects 162 and outputs a file with the results of the analysis. The rules contain information identifying which smart objects to use (instantiate), which methods (functions) to use in the smart objects, and how to react (branching logic) to the results returned by the methods.

The report generator 168 uses a report engine to produce a finished report based on the results of the analysis. The report engine may comprise an expert system of report templates, an extensive array of database-stored text, and the logic and procedures for creating the report using the results of the analysis and the file and measurement data input to the analysis engine 166. These analysis modules can be used together such as by the power quality reporting module 173 or individually as in the energy delivery analysis module 174.

The alarm module 154 of the analysis and reporting module 136 continuously reviews and analyzes data, when it is notified by the threshold detector, as the data is collected and at other points in time. An alarm may be triggered when the data exceeds user-selected thresholds or satisfies a threshold rule made up of one or more predetermined conditions. The thresholds may be provided by users via the HMI module 138. For example, simple high and low limits may be set on any measurement parameter such as volts, amps, and power. More complex combinations of conditions also may be established. An alarm may be triggered through data exchange, such as when the SCADA system 102 supplies data that indicates a breaker operation.

Once an alarm is triggered, an entry is made in an alarm log, which can be viewed from the Internet and the system administration console (e.g., web HMI 158; Console HMI 160). After an alarm log entry is made, a number of other events may be triggered. For example, a notification (e.g., an e-mail or an alphanumeric page) including the nature of the alarm may be sent to one or more selectable parties. A user-selectable report may be generated and optionally attached to the e-mail. A message may be announced at the Web HMI 158 and/or console HMI 160. An analysis rule program code may be executed.

A technician may execute a specific module to view information, such as a report. In addition, analysis rules may include access to a specific module to generate reports, charts or action lists. For example, for a given measurement device or a collection of devices, a technician may schedule a job, which is a particular report or action. The job can be scheduled or invoked when an alarm or particular condition occurs. Jobs can be simple, such as weekly routing of power quality reports, or can perform advanced calculations such as in response to predetermined or interrelated alarm conditions. System events such as monitor download failures also result in generation of an alarm and report.

The HMI module 138 may include a browser based human machine interface (HMI) 158, and an administrative console HMI 160. The browser based HMI 158 may access a web server that provides full functional access to remote users via the Internet and/or a company's intranet. In an example embodiment the browser based HMI 158 (accessible via the Internet) gives users a graphical view of the state of the system, indications on whether any alarms have occurred, full access to reports, and an unprecedented level of data analysis and manipulation through data presentation, computation, and graphing tools. The Web server may use the internet information services tools or other web support tools and generally complies with utility IT department security concerns. Users may access the system with a username and password provided by the system administrator. For example, when logging in through Windows Internet Explorer, the user may see monitors and assets complying with permissions granted by the system administrator. In addition, each user may be assigned a profile by the administrator that will define the type and combination of charts and reports the user may access or be presented automatically. In some embodiments the browser based HMI 158 provides substantially the same interactive experience as with the administrative console HMI 160, in which a user may view a tree and a site layout to select reports or other system actions.

The console (administrative) HMI 160 provides an interactive environment for a user to access all administrative functions including setup and maintenance. The console HMI 160 may be an application installed on only one PC (per substation) on a system's local area network. From the console the following functions can be performed: set up and maintain system databases; add or change graphical HMI layouts; add, delete, or edit monitors or equipment and their properties including download intervals; add, delete, or edit alarms and automated reports; add, delete, or edit rate schedules; add, delete, or edit local or Web users and assign names, passwords, and viewing levels; acknowledge or delete alarms; and view reports and data via report packages.

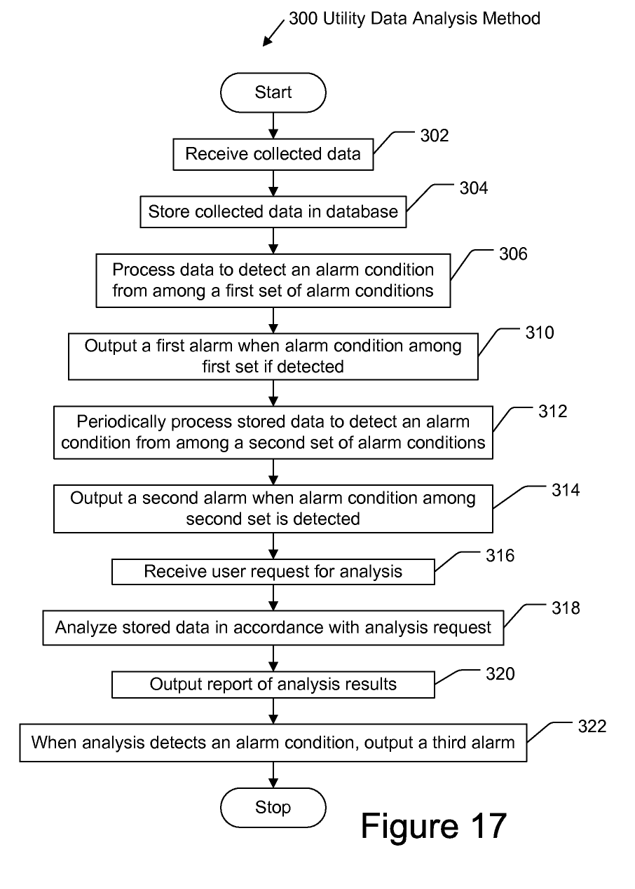

FIG. 17 shows a method 300 for analyzing utility data, according to an example embodiment of the present invention. The method 300 may be performed by the NODA system 110 in a NODA system environment 90. For example, various modules and module components may be installed on personnel computers and embedded computers at a utility's control center and at various power substations. In addition, users (e.g., administrators, technician, select clients) with appropriate privileges may access various data analysis application packages through local and remote computers and consoles, such as via a web interface 158 or console interface 160 (see FIG. 6).

At step 302, data collected via various measurement devices 92 and sensing devices 96 and/or from third party services is received, (see for example the data collection configurations shown in FIG. 9). The collected data includes non-operational data and may also include operational data. At step 304, the collected data is stored in one or more databases, (e.g., see non-operational data 114 and operational data 106 of FIG. 2; see databases 148,188 of FIGS. 6, 7 and 8; the data warehouse 212 of FIG. 9; and the database server 111 of FIG. 1). In an example embodiment the database server 111 may store the non-operational data 114 and operational data 106 in databases 148, 188 that form at least part of a data warehouse 212, which may be formed of a plurality of distributed databases 148.

At step 306, collected data may be processed to detect an alarm condition. For example, during the collection process, various processing may be performed on the data to detect one or more specific alarm conditions. In an example embodiment, a local copy of an analysis and reporting module 136 at a substation 94a, 94b may perform such alarm detection. When an alarm condition is detected at step 306, an alarm may be generated at step 310. In various embodiments one or more of the following may be performed to output the alarm: the alarm may be logged for inclusion in a report or message; a message may be sent to appropriate personnel; a report automatically may be generated.

At step 312 stored data may be periodically processed to detect an alarm condition from among a second set of alarm conditions. For example, processing may be performed for one or more specific alarm conditions which may be different, the same or overlap the alarm conditions for which data is processed during data collection. In an example embodiment the analysis and reporting module 136 residing on a computer (e.g., data collection and analysis server 109; client computer 117, 119; administrative console 115 (see FIG. 1)) may process data to detect the alarm conditions. When an alarm condition is detected, at step 312 an alarm may be generated at step 314. In various embodiments one or more of the following may be performed to output the alarm: the alarm may be logged for inclusion in a report or message; a message may be sent to appropriate personnel; an analysis and resulting report may be generated automatically.

At step 316, a user may generate an analysis request, such as by running an analysis module from among the modules 172-176. Various analysis steps may then be performed at step 318 according to the analysis requested. At step 320 an output report may be generated responsive to the analysis request. For example, a report from among those as shown in FIGS. 12-16 may be generated. In a specific embodiment, there may be hundreds or thousands of possible reports that may be generated in responsive to various analysis requests. One or more reports may be generated in response to a specific analysis request.

During the analysis performed at step 318 in response to a specific request, various data may be processed performed to detect any of various alarm conditions. The alarm conditions being tested may be defined according to the specific analysis request. Thus, data may be processed to detect different alarm conditions for different analysis requests. When an alarm condition is detected during the analysis at step 318, an alarm may be generated at step 322. In various embodiments one or more of the following may be performed to output the alarm: the alarm may be logged for inclusion in a report or message; a message may be sent to appropriate personnel; a report automatically may be generated.

It should be noted that the alarm conditions described herein may be triggered automatically as a result of processing data at any of the stages (such as those described in FIG. 10). It will be evident to those skilled in the art that the present invention may be implemented via a computer system (comprising one or more co-located or distributed computing devices) executing program code stored in a tangible medium.

It is to be understood that the foregoing illustrative embodiments have been provided merely for the purpose of explanation and are in no way to be construed as limiting of the invention. Words used herein are words of description and illustration, rather than words of limitation. In addition, the advantages and objectives described herein may not be realized by each and every embodiment practicing the present invention. Further, although the invention has been described herein with reference to particular structure, materials and/or embodiments, the invention is not intended to be limited to the particulars disclosed herein. Rather, the invention extends to all functionally equivalent structures, methods and uses, such as are within the scope of the appended claims. Those skilled in the art, having the benefit of the teachings of this specification, may affect numerous modifications thereto and changes may be made without departing from the scope and spirit of the invention.

What is claimed is:

1. A system for analyzing power grid data, comprising:
a data collection module comprising a plurality of database adaptors configured to retrieve non-operational utility data;
a data storage module in communication with said data collection module and comprising a database for storing the non-operational utility data; and
an analysis module in communication with said data storage module and configured to process the non-operational data and to provide a plurality of reports and a plurality of alarms.

2. The system according to claim 1, wherein said analysis module comprises:
an object library comprising a plurality of objects and wherein each object is configured to perform a specific analysis of utility data;
an analysis rules module linking one or more objects of the object library;
an analysis engine configured to execute the analysis rules module; and
a report generator configured to produce a report based on an output of the analysis rule module.

3. The system according to claim 1, wherein said analysis module comprises:
an alarm module configured to process non-operational data and generate alarms;
an analysis rules module configured to link a plurality of objects; and
an analysis engine configured to control the execution of said analysis rules module.

4. The system according to claim 1, wherein the non-operational data includes lightening strike data and said analysis module comprises a fault analysis module configured to correlate lightening strike data to operational data and to produce an output.

5. The system according to claim 4, wherein said fault analysis module is configured to process utility data to correlate a power line fault to a lightening strike.

6. The system according to claim 1, wherein the non-operational data includes power quality disturbance data and said analysis module comprises a power quality module configured to process power quality disturbance data to produce an output.

7. The system according to claim 6, wherein the output comprises at least one of an indication of an origin of the power quality disturbance and an indication of an impact of the power quality disturbance on a power customer.

8. The system according to claim 6, wherein said power quality module is configured to provide an output comprising an analysis of at least one of harmonics, zero-crossing errors, and voltage notches.

9. The system according to claim 6, wherein said power quality module is configured to provide one or more outputs collectively comprising analyses of harmonics, zero-crossing errors, and voltage notches.

10. The system according to claim 1, wherein said analysis module comprises a reporting module comprising a plurality of functions configured to process data of a waveform into two or more of the group of: harmonics, impedance, phasors, sag frequency, and harmonic frequency distribution.

11. The system according to claim 1, wherein at least one of the plurality of database adapter is configured to store received non-operational data in a tabular file format in a memory for temporary storage.

12. A computer system for analyzing utility data, comprising:
a data storage module comprising a database for storing utility data; and
an analysis module in communication with said data storage module and configured to process the utility data and to provide a plurality of reports and a plurality of alarms;
said analysis module comprising:
an object library comprising a plurality of objects and wherein each object is configured to perform a specific analysis of utility data;
a plurality of analysis rules modules and wherein each analysis rules module links one or more objects of the object library;
an analysis engine configured to execute each of the analysis rules modules; and
a report generator configured to produce a report based on an output of an analysis rule module.

13. The system according to claim 12, wherein the utility data includes lightening strike data and said analysis module comprises a fault analysis module configured to correlate lightening strike data to operational data and to produce an output.

14. The system according to claim 13, wherein said fault analysis module is configured to process utility data to correlate a power line fault to a lightening strike.

15. The system according to claim 12, wherein the utility data includes power quality disturbance data and said analysis module comprises a power quality module configured to process power quality disturbance data to produce the output.

16. The system according to claim 15, wherein the output comprises at least one of an indication of an origin of the power quality disturbance and an indication of an impact of the power quality disturbance on a power customer.

17. The system according to claim 15, wherein said power quality module is configured to produce an output comprising an analysis of at least one of harmonics, zero-crossing errors, and voltage notches.

18. The system according to claim 15, wherein said power quality module is configured to produce one or more outputs collectively comprising analyses of harmonics, zero-crossing errors, and voltage notches.

19. The system according to claim 12, wherein said reporting module comprises a plurality of functions configured to process data of a waveform into two or more of the group of: harmonics, impedance, phasors, sag frequency, and harmonic frequency distribution.

20. A method of using a computer system to analyze utility data, comprising:
receiving utility data;
storing utility data in a data storage system;
linking a first set of objects together and wherein each object is configured to perform a specific analysis of utility data;
executing the linked first set of objects to process utility data to provide a first result; and
outputting the first result.

21. The method according to claim 20, further comprising linking a second set of objects together and wherein each object of said second set is configured to perform a specific analysis of utility data;
executing the linked second set of objects to provide a second result; and
outputting the second result.

22. The method according to claim 21, wherein at least one object is common to both said first set of objects and said second set of objects.

23. The method according to claim 20, wherein said output comprises an alarm and a report.

24. The method according to claim 20, wherein the first result comprises an analysis of at least one of harmonics, zero-crossing errors, and voltage notches

25. The method according to claim 20, wherein the first result comprises analyses of harmonics, zero-crossing errors, and voltage notches.

26. The method according to claim 20, wherein the utility data includes lightening strike data, and the linked first set of objects are configured to correlate lightening strike data to operational data.

27. The method according to claim 20, wherein the linked first set of objects is configured to process utility data to correlate a power line fault to a lightening strike.

28. The method according to claim 20, wherein the utility data includes power quality disturbance data and said the linked first set of objects is configured to process power quality disturbance data.

29. The method according to claim 28, wherein the first result comprises at least one of an indication of an origin of the power quality disturbance.

30. The method according to claim 20, wherein one or more objects are configured to process data of a waveform into each of the group of: impedance, phasors, sag frequency, and harmonic frequency distribution.
